(19) United States
(12) Patent Application Publication
(10) Pub. No.: US 2020/0303648 A1
(43) Pub. Date: Sep. 24, 2020

(54) ORGANIC EL LIGHT-EMITTING ELEMENT AND METHOD FOR MANUFACTURING SAME

(71) Applicant: SAKAI DISPLAY PRODUCTS CORPORATION, Sakai-shi, Osaka (JP)

(72) Inventors: YUKIYA NISHIOKA, Sakai-shi, Osaka (JP); KATSUHIKO KISHIMOTO, Sakai-shi, Osaka (JP)

(21) Appl. No.: 16/615,359

(22) PCT Filed: Nov. 28, 2017
(86) PCT No.: PCT/JP2017/042620

§ 371 Date: May 15, 2020

(51) Int. Cl. H01L 51/00

(52) U.S. Cl. CPC H01L 51/006; H01L 51/0005; H01L 51/0035; H01L 51/0055; H01L 51/0069

(57) ABSTRACT

Provided is an organic EL light-emitting element including an organic layer coating film 25 which is formed into a super-fine pixel pattern by using an organic material that is an oligomer having a molecular weight of 300-5000. Also provided is a method for manufacturing the organic EL light-emitting element. The coating film 25 is formed by dropping liquid microdroplets of approximately 0.05-1 pL.

### TECHNICAL FIELD

The present disclosure relates to an organic EL light-emitting element (organic electroluminescent light-emitting element) and a method of manufacturing the same.

### BACKGROUND ART

An organic EL light-emitting element is formed such that a thin layer of organic material containing an organic light-emitting substance is sandwiched between an anode and a cathode. This organic thin layer is formed by a vapor-deposition method or a coating method. In a method of manufacturing of a vapor-deposition type organic thin layer, a supporting substrate (a substrate to be vapor-deposited) and a deposition mask are arranged overlapped, an organic material is vapor-deposited in vacuum through an opening of the deposition mask, and a thin layer is formed on the supporting substrate. In general, low molecular weight compounds are used as an organic material for a vapor-deposition type organic material. On the other hand, in a method of manufacturing of a coated-type organic EL light-emitting element, a thin layer is formed on a supporting substrate using a solution for, for example, a printing process such as a screen printing, an ink-jet process. An organic EL light-emitting element which is produced by a coating process can be produced at a lower manufacturing cost compared to an organic EL light-emitting element which is produced by a vapor-deposition process since, for example, it does not require an expensive vapor mask or equipment for high vacuum process, and an efficiency in use of an organic material in a coating process is higher than a vapor-deposition process. However, it is difficult to produce a good quality thin layer using a coating process since low molecular weight compounds tend to be easily crystalized. Therefore, polymer compounds having a high amorphous property have been used as an organic material in the coating process. For example, Patent Document 1 describes a polymer compound containing a specific repeating unit as an organic material for a coated-type organic EL light-emitting element, which can be used as a light-emitting material or charge transport material. A polymer compound used in a coating process usually contains at least a number of several tens or more of such repeating units.

### PRIOR ART DOCUMENT

### Patent Document

Patent Document 1: JP 2011-223015 A

### SUMMARY OF THE INVENTION

### Problems to be Solved by the Invention

As mentioned above, a polymer compound is used for an organic material for a coated-type organic EL light-emitting element. However, in the conventional coated-type organic EL light-emitting element, it is difficult to coat an organic material in a minute dot pattern since a size of a droplet of the organic material is hardly reduced even using an ink-jet method. Therefore, an attempt has been made to have a coating solution within a pixel by devising an insulation bank arrangement when the display apparatus is large-sized and the pattern formation has large area, for example, a size of each pixel for the display apparatus is a long-side length of 210 μm or more and a short-side length of 70 μm or more.

However, an area for each pixel of the display apparatus becomes very small with the reduced weight, size, and thickness and the high definition of the recent electronic apparatus such as a portable device, making unable to separately coat on each pixel even using an ink-jet method, since the droplet spreads across more than one pixels. Also, the purification of polymer compounds is difficult, and it is hard to obtain highly purified polymer compounds. Therefore, when the polymer compounds are used for an organic EL light-emitting element, a luminescent color purity, a light emission efficiency, a brightness and so on might be reduced. Further, if the molecular weight of the polymer compound becomes too high, forming a homogeneous layer may become difficult due to a gelation of polymer compounds.

Further, it has been generally known that the light emission efficiency of the low molecule weight compounds is greater than that of the polymer compounds, the life of the low molecule compounds is longer than that of the polymer compounds, variations in color realized with the low molecule weight compounds is greater than that realized with the polymer compounds, and the performance in blue light emission of the low molecule weight compounds is especially superior compared to that of the polymer compounds. However, a coating solution containing a low molecule weight compound has a high fluidity, thereby the coating solution spreads right after being ejected from a discharge nozzle of the ink-jet apparatus, making it difficult to form a liquid drop of good quality, and, since the low molecule weight compounds tend to be easily crystalized as described above, a layer of a low molecule material is formed in such a way that the material is inhomogeneously distributed, and thus it is difficult to use low molecule weight compounds for a conventional method of manufacturing a coated-type organic EL light-emitting element.

As described above, when the polymer compounds are used for an organic material, it is difficult to prepare a small liquid drop. Therefore, when a pixel size becomes small, a problem arises that a separate coating with high definition on an electrode of the small pixel is unable to be carried out even using an ink-jet method. Further, the difficulty has been enhanced in selectively coating a small-sized desired area with the organic material, due to a droplet diameter of a liquid drop to be ejected, while a technique for manufacturing an organic layer with a smaller size and a higher definition for, for example, a display apparatus for a smartphone is demanded.

An object of the present invention is to solve those problems and to provide an organic EL light-emitting element having an organic layer with a small size and a high definition pattern by using an inexpensive printing method for the organic layer formation, and a manufacturing method thereof.

### Means to Solve the Problem

An organic EL light-emitting element according to the first embodiment of the present application comprises a substrate, a first electrode provided on a surface of the substrate, an insulation bank formed to surround at least part of the first electrode, an organic layer formed on the first electrode surrounded by the insulation bank, and a second electrode formed on the organic layer, wherein the organic layer is a coated-type organic layer comprising an oligomer of an organic material, and the oligomer has a molecular weight of 300 or more and 5000 or less.

A method of manufacturing an organic EL light-emitting element according to the second embodiment of the present application comprises forming a first electrode on a surface of a substrate, forming an insulation bank to surround at least part of the first electrode, forming a coated-type organic layer on an area of the first electrode surrounded by the insulation bank, and forming a second electrode on the organic layer, wherein a step for forming the organic layer is conducted by applying a droplet with a volume of 0.05 pL or more and 1 pL or less of a liquid composition comprising an oligomer of an organic material using an ink-jet process.

### Effect of the Invention

According to the first embodiment of the present application, an organic EL light-emitting element is formed with a coated-type organic layer containing an oligomer of an organic material, thereby a coated-type organic EL light-emitting element is provided in which each pixel of a display apparatus can be constituted by a separate coating of even a very small light-emitting area with a size of, for example, 10 μm square to 50 μm square. Further, according to the second embodiment of the present application, since a coating solution containing an oligomer of an organic material is used and thus a liquid droplet with a volume of 0.05 pL or more and 1 pL or less is ejected and dropped using an ink-jet process, an organic EL light-emitting element in which a coated-type organic layer is formed in a high definition pattern can be provided. As a result, a small, high-definition organic EL light-emitting element can be obtained at a low cost and a small, high-definition display apparatus can be manufactured inexpensively.

### BRIEF DESCRIPTION OF THE DRAWINGS

FIG. 1A shows a coating process in a method of manufacturing an organic EL light-emitting element according to one embodiment of the present application.

FIG. 1B shows a state in which a coated layer containing an oligomer of an organic material is formed on an electrode during a manufacturing process.

FIG. 1C shows a cross-sectional view of an organic EL light-emitting element according to one embodiment of the present application.

FIG. 2 shows a relation of a volume per one drop of a liquid drop of a coating solution to a molecular weight of a compound in a coating solution for an ink-jet process.

FIG. 3 shows a coating process in a method of manufacturing an organic EL light-emitting element according to one embodiment of the present application in which an organic layer is formed in an area of a rectangular shape.

FIG. 4 shows a flowchart of a manufacturing process according to one embodiment of the present application.

### EMBODIMENT FOR CARRYING OUT THE INVENTION

The invention will be further described below. The embodiments described below are intended only to provide an example of the disclosure and the invention is not limited to certain embodiments described below.

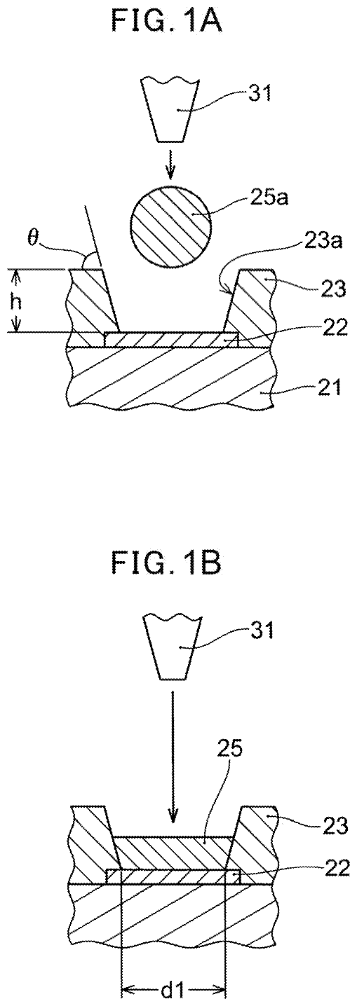

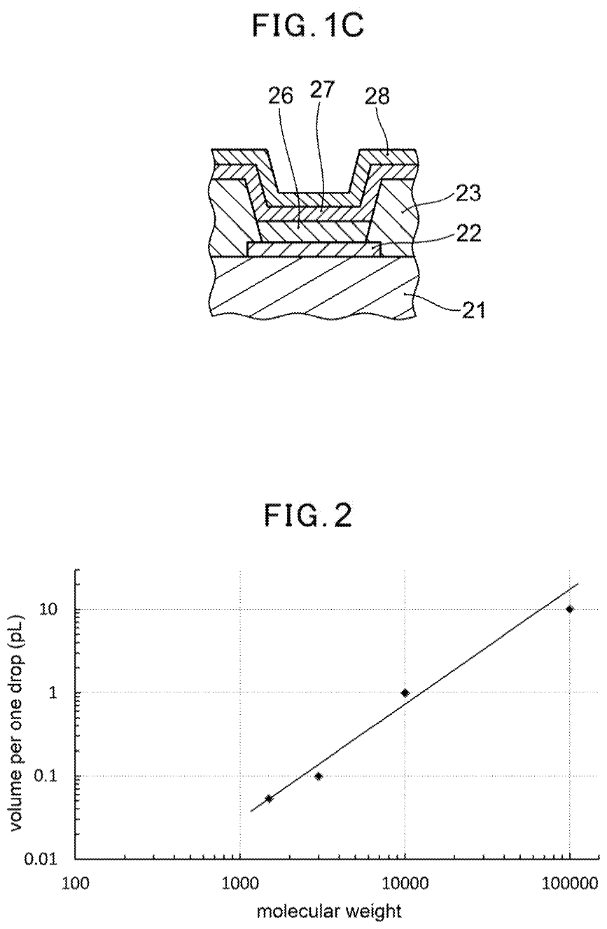

As illustrated in FIG. 1C, which shows a schematic cross-sectional view of an organic EL light-emitting element, an organic EL light-emitting element according to the presently illustrated embodiment comprises a substrate 21, a first electrode 22 (an anode, for example) provided on a surface of the substrate 21, an insulation bank 23 formed to surround at least part of the first electrode 22, an organic layer 26 formed on the first electrode 22 surrounded by the insulation bank 23, a second electrode 27 formed on the organic layer 26, and a barrier layer 28 formed on the second electrode 27. The organic layer 26 is formed by a coated-type organic layer containing an oligomer of an organic material, in which the oligomer has a molecular weight of 300 or more and 5000 or less.

The term “coated-type organic layer” is used herein to refer to the organic layer prepared by drying a coated layer formed by coating process, for example, a coated layer of an organic material formed using a dispenser and a coated layer formed by a printing process such as a screen printing or an ejection of organic material drops by ink-jet process.

As described above, the conventional, coated-type organic EL light-emitting element has a problem in that the element cannot be formed in a small-sized light-emitting area. When coating an organic material on an area of the electrode, which will constitute each pixel, by, for example, ink-jet process for manufacturing a display apparatus, it is necessary to adjust a physical property of a coating solution ejected from a nozzle of ink-jet apparatus and optimize a ejecting speed of a liquid drop of a coating solution when ejected and a printing condition of an ink-jet apparatus, however, the inventors have found out that among those a size of a liquid drop of a coating solution when being ejected is an important factor to determine a possible size of an area to which an organic layer is provided, and that it is very important to adjust a size of a liquid drop to a desirable size at a pattern forming using an ink-jet process. For example, in order to coat an area to be coated with a high definition pattern by ejecting a coating solution containing an organic material from a nozzle of the ink-jet apparatus, it is necessary to reduce a droplet diameter of a liquid drop to be ejected from a nozzle of the ink-jet apparatus according to the size of a small area to be coated. However, with a conventional coating solution, a volume of a liquid drop when a coating solution of an organic material being ejected using an ink-jet process is about 5 pL to about 30 pL in average, and it is impossible to reduce the volume of a coating solution per one drop to 1 pL or less. A lower limit of a volume of a liquid drop of a coating solution of more than 1 pL is excess for a size of a pixel area on the electrode to which an organic layer will be provided when intending to provide a pixel with a resolution around 500 ppi or a higher pixel density for a display apparatus with a size of the smartphone. If a diameter of the nozzle is reduced in order to decrease a droplet diameter of a liquid drop, a clogging will occur and an ejection from the ink-jet apparatus cannot be realized. If a content of a solvent component in the coating solution is reduced, a viscosity of the coating solution will be increased, which makes it impossible to evenly eject a coating solution from a nozzle of the ink-jet apparatus and may cause a nozzle clogging. Further, for a conventional coating solution, a polymer compound, which is used as an organic material in the conventional coating solution, has a low solubility in a solvent, and thus an amount of the solvent required for the coating solution about ten times greater than the amount of a polymer compound. Therefore, the solvent which constitutes the most part of the dripped coating solution should be evaporated by drying, requiring a long time for a formation of an organic layer. Further, if the amount of the dripped coating solution is large, there would be a possibility that a thickness unevenness of the organic layer may occur while the solvent in the coating solution is dried to form the organic layer. It has been known that such a thickness unevenness is the factor causing, for example, a luminance unevenness or a light emission color unevenness to an organic EL light-emitting element. Moreover, while using a conventional coating solution requires to increase a size of an area on which a coating solution is coated, the size of the area on which a coating solution is coated should be small to obtain a display apparatus formed by a large number of pixels.

Therefore, there is a need for a separate coating of even a very small light-emitting area, however, a size of a droplet of the conventional coating solution cannot be reduced, and the inventors conducted extensive studies and investigated the reason why the size of the droplet of the conventional coating solution cannot be reduced. As a result, the inventors found out that this is because the molecular size of an organic material to be dissolved in the solvent is large since a polymer compound is used as an organic material. As a result of further extensive studies of inventors, the inventors found out that, as shown in FIG. 2, a size of a liquid drop is largely affected by a molecular weight of an organic material. The inventors ascertain that the reason why small droplets cannot be formed is attributed to a fact that a solute (an organic material) in the conventional coating solution is a polymer compound having a high degree of polymerization and a large molecular weight of 10000 or more. It is considered that a size of a liquid drop is affected by a concentration of an organic material in a coating solution (a solubility of an organic material in a solvent) or a viscosity of a coating solution, however, the inventors conducted a test under the condition in which a concentration is as high as possible, yet a dropping of the solution is enable to be conducted.

As a result, as clearly shown in FIG. 2, the inventors found out that when a molecular weight is 300 or more and 5000 or less, preferably about 3000 or less, more preferably 500 or more and 1000 or less, a liquid droplet volume per one drop can be set to about 0.05 pL to about 1 pL. The inventors conducted various studies with different polymerization methods and tested various compounds with a smaller molecular weight, i.e. a smaller degree of polymerization, and, as a result, the inventors found out that a liquid drop with the above-mentioned size can be obtained by using an organic material having a certain polymerization degree, which can form an oligomer (generally around or less than an icosamer), preferably an dimer to decamer.

As described above, for the conventional, coated-type organic EL light-emitting element, a size of a light-emitting area of the organic EL light-emitting element cannot be reduced to 70 μm×70 μm or less. This means that when a length of one side of a light-emitting area is 70 μm or less, a liquid drop will overflow from the area. Therefore, a pixel size corresponding to a 20-inch QHD display, which is, a size of 70 μm×210 μm, is a limit size of the area that can be formed in the conventional, coated-type organic EL light-emitting element. Even with this size of light-emitting area, various improvements to an insulation bank were needed, as described above. Those improvements are described below. The exemplary organic EL light-emitting element according to the present application will be described in the followings by referring to FIGS. 1A to 1C, in which an insulation bank 23 is formed in a periphery of a first electrode 22, and an organic layer 26 is coated on the first electrode 22 in an opening 23a surrounded by the insulation bank 23. This organic layer 26 forming area constitutes a light-emitting area. When a plurality of organic EL light-emitting elements are arranged in matrix form on the organic layer 26 to form a display apparatus, a second electrode 27 (see FIG. 1C) may be formed across the entire surface continuously.

In the conventional, coated-type organic EL light-emitting element having such a structure, when the organic EL light-emitting elements are arranged in matrix form in a display apparatus, a coating solution overflows an opening 23a surrounded by the insulation bank 23 and spreads to neighboring light-emitting area since a liquid droplet volume per one drop ejected by an ink-jet process is large, as described above. To avoid this problem, the surface of a sidewall of the opening 23a surrounded by the insulation bank 23 and the top surface of the insulation bank 23 are formed to have a liquid repellent property. With such a liquid repellent treatment, a dripped coating solution is likely repelled by the insulation bank 23 even when the volume of the dripped coating solution is larger than a volume within the opening 23a, and the coating solution is pulled into a spherical shape due to a surface tension of the coating solution, raised in the vertical direction and kept in an opening 23a, without overflowing the insulation bank 23 and spreading to areas of neighboring light-emitting elements from a small light-emitting area. To obtain such a liquid repelling property, an insulation bank 23 is need to be either formed by a fluorine resin containing fluorine, such as a polyimide containing fluorine, or a silicone resin, or subjected to a plasma treatment for treating a surface of the insulation bank 23 by, for example, CF₄ based gas, both of which can be a difficult work and may increase a manufacturing cost. There is also a possibility that the fluorine gas may have an adverse effect on an organic layer. Further, it seems difficult to completely prevent the wetting spread of the coating solution to the neighboring light-emitting areas.

Further, as for other attempts, an attempt to increase a height h of an insulation bank 23 from a first electrode 22 (see FIG. 1A, hereinafter simply referred to as “a height of an insulation bank 23”) has been made. In this attempt, an insulation bank 23 is formed so as to have a height h of 2 μm or more, resulting in an increment of a volume within an opening 23a, and thus, a rather large liquid drop can be kept in an opening 23a. However, when a height h of an insulation bank 23 is increased, a height difference between a surface of an organic layer 26 and a top surface of the insulation bank 23 will become large. This leads a problem in that a second electrode 27 which is formed across an entire surface of an organic layer 26 and top surface of the insulation bank 23 is likely disconnected stepwisely. To prevent this stepwise disconnection problem, it is necessary to form a second electrode 27 to have a thickness of 1 μm or more. This causes problems in that a time required for forming a second electrode 27 will become longer, and that more material will be needed for forming a second electrode 27, which results in an increment in the cost, and in addition to these problems, light transmittance can be worsened. As a result, this causes a problem in that an organic EL light-emitting element of a top emission type, in which light is taken out from a top surface, i.e. from a surface including the second electrode 27, cannot be produced. Further, when the height of the insulation bank is increased, light emissions in oblique directions may be blocked, resulting in poor viewing angle characteristics. Further, in order to form an insulation bank with a high height, it is necessary to form an insulation bank in such a way to have a large width. This demands a wide pixel pitch, and thus a high definition pattern is hard to be obtained.

Further, as for other attempts, an attempt to prevent a coating solution from spreading over a neighboring light-emitting area has been made by forming a shape of an insulation bank 23 to be a reversed tapered shape in which a spacing between sidewalls of the insulation bank 23 in a vertical cross sectional view is decreased from a surface of the first electrode 22 toward a top surface of the insulation bank 23. However, making such a reversed tapered shape is difficult, and further, it causes a problem in that a stepwise disconnection of a second electrode 27 which is formed across an entire surface of an organic layer 26 and top surface of the insulation bank 23, as described above, may occur more frequently. Therefore, a stepwise disconnection problem of the second electrode 27 will become even severe compared to in the above-described attempt to increase a height h of the insulation bank 23, and thus, it is necessary to form a second electrode 27 much thicker.

On the other hand, in an exemplary embodiment according to the present application, by using an organic material with a smaller degree of polymerization, which is neither a polymer compound nor a low molecule weight compound and has a molecular weight of 300 or more and 5000 or less, preferably about 3000 or less, more preferably 500 or more and 1000 or less, in other words, by using an organic material of an oligomer, preferably an oligomer from a dimer to a decamer, as an organic material to be dissolved in a coating solution, a small liquid drop of a coating solution having a volume per one drop of about 0.05 pL or more and about 1 pL or less was obtained. This enables to form an insulation bank 23 to have a smaller height h since there is no possibility that a coating solution 25a overflows an opening 23a (see, FIGS. 1A and 1B). A coating solution 25a will not overflow even if a height hi of an insulation bank 23 is, for example, about 1 m or less.

Further, according to the presently illustrated embodiment, there is no need to form an insulation bank 23 in a reversed tapered shape. Thus, an insulation bank 23 may be formed in a forward tapered shape (a shape that is a reversed shape of the above-described reversed tapered shape, i.e. the shape in which spacing between sidewalls of the insulation bank 23, which forms an opening, in a vertical cross sectional view is increased from a surface of the first electrode 22 toward a top surface of the insulation bank 23). In other words, according to the presently illustrated embodiment, the insulation bank 23 can be formed to have a taper angle θ to the horizontal plane of the insulation bank 23 (see, FIG. 1A) of 10° or more to 90° or less. In this case, the insulation bank 23 can be manufactured more easily compared to an insulation bank 23 with a reversed tapered shape. The insulation bank 23 may also be formed in a forward tapered shape with a taper angle θ of, for example, about 80° or less. This may further prevent a stepwise disconnection problem of the second electrode 27. As a result, the stepwise disconnection problem never occurs even when the second electrode 27 is formed with a thin thickness, and a light-emitting element can be formed either as a top emission type light-emitting element or as a bottom emission type light-emitting element.

Since a small-sized liquid drop was able to be formed as described above, the organic layer 26 was formed successfully and precisely even in a light-emitting area with a small size, such as a small-sized light-emitting area of about 10 μm×10 μm, which is much smaller compared to the conventional size of 70 μm×210 μm, without employing the above-described attempts that had been made for the conventional, coated-type organic EL light-emitting element to the insulation bank 23. As a result, even a ht-emitting element to be used for a small, high definition display apparatus such as a smartphone can be formed with a coated-type organic layer. Further, it was found that a concentration of solute in the coating solution can be increased to about 10 mass % to 30 mass % and thus the organic layer can be formed efficiently even in the small light-emitting area.

A coating solution containing an oligomer according to the presently illustrated embodiment is suitably applicable to an area having a similar size to the conventional, coated-type organic EL light-emitting element. However, it is particularly effective to a light-emitting area of 3500 μm² or less, preferably 2500 μm² or less, which has not been able to be formed from the conventional coated-type organic layer.

Since there is no need to subject a surface of the insulation bank 23 to a liquid repellent treatment, there is no need to form an insulation bank 23 using a fluorine resin containing fluorine or a silicone resin, and a plasma treatment of a surface of the insulation bank 23 by, for example, CF₄ based gas is also not necessary. Not only that this makes a manufacturing process of an element very simple, but also it can exclude an adverse influence that may be caused by an effusion of fluorine from the insulation bank 23. For example, preferably a polyimide-based resin containing no fluorine may be used for an insulation bank 23. As a result, a life prolongation of the elements can be achieved. Further, in the presently illustrated embodiment, not only is there no need to conduct a liquid repellent treatment, but also an insulation bank 23 may be even formed so as to have a hydrophilic property. It may be preferable to form an inside of an opening 23a surrounded by the insulation bank 23 to have a hydrophilic property, since a dripped coating solution can be easily spread up to a peripheral portion of a first electrode 22. A term of hydrophilic property as referred herein involves a resin with no liquid repellent property as well as a resin to which no specific treatment, i.e. no liquid repellent treatment, has been conducted. Therefore, the meaning of an insulation bank 23 having a hydrophilic property as referred herein involves not only the insulation bank to which a hydrophilic treatment is particularly conducted, but also the insulation bank to which a liquid repellent treatment is not conducted. However, the insulation bank 23 may be formed with a particularly hydrophilic material such as, for example, polyimide or polyamide, or a surface of the insulation bank 23 may be modified to have a hydrophilic property by a treatment such as, for example, plasma surface treatment, UV irradiation treatment, ozone treatment. For example, by forming an insulation bank 23 to have a hydrophilic property, such as a contact angle of a surface of an insulation bank 23 to water of 60° or less, a compatibility between a coating solution containing an organic material and a surface of an insulation bank 23 may be improved, and an organic layer 26 may adequately fill a space from a bottom of an opening 23a to a sidewall of an opening 23a. As a result, a surface of an organic layer 26 becomes higher at a contact point of an organic layer 26 with a sidewall of an insulation bank 23 (a pinning position).

As described above, the inventors found out that, in order to form a coated-type organic layer 26, it is necessary to adopt the compound with a molecular weight of about 300 or more and about 5000 or less, preferably about 3000 or less, more preferably about 500 or more and about 1000 or less as a compound in the coating solution to obtain a small droplet of the coating solution. The molecular weight for each compound may vary depending on the organic material, however, arranging a molecular weight within this range means arranging a degree of polymerization to the degree the oligomers have. An oligomer is generally around or less than an icosamer, however, in the presently illustrated embodiment it may be preferable that a molecular weight of the compound is smaller, and thus even among the oligomers a dimer to decamer may be preferable. By using an oligomer with a polymerization degree of this range, a small droplet of a coating solution which has a volume per one drop of about 0.05 pL or more and about 1 pL or less and a nearly spherical shape can be formed, and a coated-type organic layer can be obtained via an ink-jet process on even a pixel with a small-sized area of, for example, 100 μm² or more and 2500 μm² or less, preferably 1200 μm² or less, more preferably 850 μm² or less, in other words, 17 μm×50 μm or less, or 25 μm×25 μm or less. Thus, an organic EL light-emitting element according to the presently illustrated embodiment can form a pixel of the organic EL display apparatus, which has a resolution around 500 ppi or a higher pixel density for an apparatus with a size of the smartphone.

In the presently illustrated embodiment, an oligomer may be obtained, for example, by lowering the reaction temperature at some point in an early period of polymerization reaction, for example, about 60 min. after starting the polymerization reaction, for preparing an organic material of a conventional polymer compound, or by terminating a polymerization reaction through a process of, for example, removing a catalyst for polymerization reaction. By applying an organic material containing this kind of oligomer as an organic material for a coating solution, a small droplet which has a volume per one drop of about 0.05 pL or more and about 1 pL or less can be formed if a size of an ejecting port of a nozzle of an ink-jet apparatus is set to about 10 to 20 μm in diameter, and thus there is no risk at all that a coating solution 25a crosses an insulation bank 23 and overflows even when the coating solution 25a is coated to the above-described small light-emitting area. As a result, an organic layer was formed successfully by a coating process even on an area of the light-emitting area formed with the above-described high definition pattern without an occurrence of color mixing problem. The coating solution cannot pass through a nozzle having a small ejecting port, just as the coating solution containing an organic material of a conventional polymer compound cannot, when a molecular weight of the compound is larger and a degree of polymerization is higher than those described above, and thus the organic material cannot be ejected from a nozzle of the ink-jet apparatus, and if an ejecting port with a larger size is used, an excess amount of an organic material, which overflows from a pixel with small area, is dropped and a coated-type organic layer cannot be formed on a small area all pixel). A concrete and exemplary method for preparing an oligomer will be described below. In order to obtain such a small droplet, a viscosity of a solution will be important, and it may be preferable that a solution has a viscosity of, for example, 0.6×10⁻³ Pa·s or more and 3×10⁻³ Pa·s or less by selecting and adjusting a kind and a quantity of a solvent to be used.

Even when an area to which an organic layer 26 will be formed is a small area with a size of 2500 μm² or less, as described above, the area can be coated via an ink-jet process. However, the shape of an area to be coated is a rectangular shape, and if a length of one side of the rectangular shape is too small (a width of the rectangle is too narrow), it becomes impossible to apply a liquid drop to the area precisely. Therefore, when a shape of the area to which an organic layer 26 will be formed has a rectangular shape, it may be preferable that a short side of the rectangle is 10 μm or more. In other words, a squared value of this lower limit of a length of the short side will be a lower limit of a size of a pixel which can be formed by the presently illustrated embodiment. It should be appreciated that a shape of the area to which an organic layer 26 will be formed, i.e. a shape of a pixel, is not limited to a rectangular shape or a square shape, and may be a round shape, elliptic shape, or polygon.

An upper limit of a size of the area to which an organic layer 26 is formed is not particularly limited. When the area to be coated is large, a cross-sectional area of an ejecting port of a nozzle will be increased so that even a large area may be formed in a relatively short time. However, the presently illustrated embodiment of the present application is significantly advantageous when the area has a size of 3500 μm² or less, preferably 2500 μm² or less, which is the size that is never obtained with a conventional organic material containing a polymer compound.

An organic layer 26 may include one or more organic layers such as a hole transport layer or an electron transport layer, other than a light-emitting layer. In case where the organic layer 26 is formed with a plurality of layers, a material for each layer should be an organic material containing an oligomer as mentioned above. Further, an organic layer 26 according to the presently illustrated embodiment may further include an optional layer between the organic layer 26 and a first electrode 22 or a second electrode 27, or between each of the organic layers when the organic layer 26 is formed by one or more organic layers. Further, a TFT (not indicated) or a planarization layer (not indicated) and so on may be formed on a substrate 21. It should be noted that an organic EL light-emitting element shown in FIGS. 1A to 1C according to the exemplary embodiment described below is a top emission type, however, as described above, it may be formed either for a bottom emission type or a both sides emission type.

An organic EL light-emitting element according to the presently illustrated embodiment may be applicable to an illumination apparatus by sealing one or more organic EL light-emitting elements with an envelope (a covering layer) which has at least a translucent front surface, or to a display apparatus by arranging a plurality of light-emitting elements in matrix form. When applied to an illumination apparatus, light-emitting elements of three colors, red (R), green (G) and blue (B) are enclosed in one envelope, providing a white light-emitting illumination apparatus. A white light or a light of any other desirable colors emitting illumination apparatus may be also formed by covering a monochromatic light-emitting element by a fluorescent resin.

When applied to a display apparatus, sub-pixels of three colors, R, G and B are formed respectively for each pixel (one pixel) arranged in matrix form, providing a full-color display apparatus. In this case, a size of each sub-pixel is about one-thirds of the size of one pixel, and its area is smaller than the area of one pixel. A material for an organic layer for each sub-pixel and a planar shape of a sub-pixel could be different each other, however, a layered structure formed with, for example, a first electrode 22, an organic layer 26, a second electrode 27 is same, and thus a sub-pixel is herein described as one light-emitting element (one pixel) without distinguishing a sub-pixel from a pixel. An arrangement of the pixels is not particularly limited, and the pixels may be arranged, for example, in a mosaic arrangement, a delta arrangement, a stripe arrangement, and a pentile arrangement. In each pixel, a first electrode 22 of an organic EL light-emitting element is connected to a driving element, and a predetermined color corresponding to each pixel is emitted by the on-off control of each pixel and various luminescent colors are realized by mixing different colors.

A substrate 21 may be a support substrate formed with, for example, a glass plate, a polyimide film. In case where the substrate 21 does not need to be translucent, a metal substrate or a ceramics substrate may be used as well. When applied to a display apparatus, though FIGS. 1A to 1C do not illustrate completely, a driving element such as TFT is formed on a position corresponding to an arrangement place for a pixel. A planarization layer, which is formed by a material such as acrylic resin or polyimide, may be formed on a driving element for planarization. A material for a planarization layer is not limited to those described above, and may be an inorganic material such as SiO₂, SOG, however, an organic material may be preferable to be applied in order to eliminate irregularities of the surface easily. A first electrode 22 is formed by a combination of a metal layer such as Ag or APC and an ITO film at a portion of a surface of the planarization layer which corresponds to an area to which an organic EL light-emitting element is formed. An organic layer 26 is coated on the first electrode 22.

An insulation bank 23, which is formed by, for example, a silicon oxide, a silicon nitride, a silicon oxynitride, an acrylic resin, a polyimide resin, and a novolak-type phenol resin, is formed around a first electrode 22 which constitutes each pixel, as described in FIGS. 1A to 1C, in order to divide pixels as well as to prevent a contact between the first electrode 22 and the second electrode 27. The insulation bank 23 is formed in such a way that it surrounds at least part of the first electrode 22. As shown in FIG. 1A, in the presently illustrated embodiment, the insulation bank 23 is formed in such a way that it covers a peripheral portion of the first electrode 22 which is formed in a predetermined area. However, an insulation bank 23 may be formed so as to contact with the first electrode 22 without covering the first electrode 22 or formed separately from the first electrode 22. In other words, an insulation bank 23 may be formed to surround a larger area than the area to which the first electrode 22 is formed. However, the area to which the light-emitting element is formed is very small, as described above, it may be preferable to form the insulation bank 23 so as to overlap with a peripheral portion of the first electrode 22.

In either case, it is important to form a layered structure in which the first electrode 22 and the second electrode 27, which is formed after a formation of the organic layer 26, are never in contact with one another (inducing a leakage). Therefore, it may be preferable that an organic layer 26 is provided in an area surrounded by an insulation bank 23 so as to cover an entire surface of the first electrode 22 which is exposed in an opening 23a surrounded by the insulation bank 23 (not covered with the insulation bank 23). A second electrode 27 may be formed on the organic layer 26. However, an organic layer 26 may be formed on the first electrode 22 to have a size smaller than the size of the first electrode 22 without covering an entire surface of the first electrode 22, and a second electrode 27 may be formed on the organic layer 26 to have a size further smaller than the size of the organic layer 26.

An area of the first electrode 22 surrounded by this insulation bank 23 may be formed such that a size of the area is to be a 17 μm×50 μm rectangular shape for a high definition panel of a medium or large size, or a 25 μm×25 μm square shape for a high definition panel of a small size for, for example, a hand-held display apparatus, referring to d1×d2 shown in FIG. 1B (d2 shows a size in the direction vertical to the paper surface and is not shown in the figure). Associated with recent trends of a miniaturization and a definition enhancement of electronic apparatus as described above, this size tends to become smaller and smaller, however, a precise coating of the small area can be conducted by using the above-described coating solution, even when a size of the small area, which is the area of the first electrode 22 surrounded by the insulation bank 23, is about 10 μm². Specifically, for example, the coating solution according to the exemplary embodiment is suitable to coat an area with a size of about 520 μm² or more and about 850 μm² or less. The coating solution according to the exemplary embodiment may be coated even to an area of about 10 μm×10 μm. The above-mentioned length, as described as a length of one side of the pixel having a rectangular shape, is merely an example, and a size of an area to be coated may have any sizes that correspond to various pixel shapes for the desired display apparatus.

Among the coated-type organic layers 26, organic materials each correspond to a color from R, G, and B may be used for each of light-emitting layers. However, a light-emitting layer may be formed using the same material, and a color filter may be provided on the surface of the light-emitting layer to obtain a color R, G, or B through a color filter. Further, the organic layer 26 other than a light-emitting layer may include a hole transport layer or an electron transport layer, or a layered structure thereof. In case where a light-emitting property is considered the most important, it may be preferable to coat a material suitable for a light-emitting layer separately for forming such a hole transport layer or such an electron transport layer. However, when using a coating process, it is possible to form an organic EL light-emitting element with a coated-type organic layer 26 which includes a fewer number of layers by mixing organic materials each of which forms respective layers.

For example, in order to form the organic layer 26, as described, for example, in FIG. 1A, a coating solution 25a of an organic material containing an oligomer is dropped onto a first electrode 22 surrounded by an insulation bank 23 from a nozzle 31 of an ink-jet apparatus. As a result, a coated layer 25 is formed as described in FIG. 1B. The coated layer 25 spreads into an area surrounded by an insulation bank 23, which serves as a dam, and remains in the area, and can stick to an insulation bank 23 without forming a spherical shape since the insulation bank 23 does not have a liquid repelling property, thereby a surface of the coated layer 25 is planarized. By drying this, a solvent component in the coating solution 25a is evaporated, providing a thickness being about one-thirtieth of the thickness of the coated layer 25, for example, about 10 to 20 nm per one layer (per one material), By conducting this coated-type organic layer 26 formation process repeatedly with necessary materials, a coated-type organic layer 26 is formed as described in FIG. 1C. In FIG. 1C, the coated-type organic layer 26 is descried in one layer, however, as described above, in general the coated-type organic layer 26 will be formed with a plurality of layers.

As described above, in the presently illustrated embodiment, the element is a top emission type in which a light is emitted from the surface of the element which is the opposite to the surface including a substrate 21 in FIGs, and thus a second electrode 27 formed on the organic layer 26 is formed of a translucent material such as a thin eutectic layer composed of magnesium and silver. Other materials such as aluminum can be also used. It should be noted that in case where the element is a bottom emission type in which a light is emitted through the substrate 21, a material such as ITO, In₃O₄ may be used for a first electrode 22 and a metal having a small work function such as Mg, K, Li, Al may be used for a second electrode 27. On the surface of the second electrode 27 a barrier layer (a covering layer) 28 (see FIG. 1C) may be formed. This covering layer 28 may be replaced with a seal layer (an envelope), which is described below. It may be preferable to form a barrier layer 28 with a plurality of layers that are formed by the material such as Si₃N₄, SiO₂, since such a barrier layer 28 could provide a fine layer quality. The whole part may be sealed by a seal layer (not indicated) formed by, for example, a glass or a resin film with a moisture-resistant property so as to be formed such that the organic layer does not absorb water.

As described above, an oligomer of an organic material in the presently illustrated embodiment refers to the organic compound having a smaller molecular weight than a polymer compound, which is used as an organic material for a so-called polymer compound type organic EL light-emitting element and coated by a conventional coating method, and a larger molecular weight than a low molecular weight compound, which is used as an organic material for a so-called low molecular weight compound type organic EL light-emitting element and deposited by a vapor-deposition method. With this range of molecular weight, the organic material of the presently illustrated embodiment has a solubility to a solvent sufficient to be applied for a coating solution 25a for ink-jet process which is ejected from a nozzle of ink-jet apparatus to form a coated layer 25 by coating. A concentration of the oligomer in the coating solution 25a according to the presently illustrated embodiment may be adjusted to a concentration which enables to form an organic layer 26 with a desirable thickness, and it can be, for example, about 10 mass % to about 30 mass %. Further, as described below, since only the oligomer having a desirable polymerization degree can be isolated and purified after the synthetic reaction as the oligomer of the organic material of the presently illustrated embodiment, it has no molecular weight distribution, and thus, the color purity and brightness can be enhanced when such an organic material is applied to an organic EL light-emitting element compared to the element where an organic material containing a polymer compound which is not easily purified and difficult to be obtained as a highly purified compound is used. Also, to use an oligomer of the organic material as an organic material may prevent a crystallization or aggregation of the organic material when being coated, and thus, a stability of a layer of the organic layer 26 to be formed may be increased compared to the layer formed from the organic material containing a low molecule weight compound which is, for example, crystalized easily in general. If a crystallization or aggregation of the organic material occurs in the organic layer, a brightness of the area in which a crystallization or aggregation occurs and a layer thickness is relatively increased is relatively decreased because an amount of the current to be injected is reduced compared to the area in which such a crystallization or aggregation does not occur, possibly causing variation in the distribution of the light emission intensity within a pixel. Also, there would be a possibility that the lifetime of the element itself may be shortened because of a deterioration occurred in the area having a thin thickness due to a concentration of current in the area having a relatively thin thickness. The occurrence of this kind of problems can be prevented by using an oligomer of the organic material of the exemplary embodiment of the present application for an organic layer 26 of the light-emitting element. Therefore, an organic EL light-emitting element with a high definition having a long lifetime and superior light emission intensity can be provided by a method for manufacturing a coated-type element using a relatively inexpensive printing method.

An oligomer of an organic material to be use for an organic layer 26 of the organic EL light-emitting element of the presently illustrated embodiment may be, but not limited to, an oligomer having a structure, in which two or more and 10 or less of monomers containing a structural unit which contributes to an light-emitting property of the material generally applicable to a light-emitting layer of the organic EL light-emitting element are polymerized, and the material generally applicable to a light-emitting layer of the organic EL light-emitting element refers to, for example, materials used as the conventional, dye-based material or polymer material.

Specifically, an oligomer to be used for an organic material of the organic EL light-emitting element of the presently illustrated embodiment may be, but not limited to, for example, a polymer of monomers each of which includes a structural unit represented by a general formula (I): —[Y]—, wherein Y includes a skeleton selected from, for example, a triarylamine skeleton, an oxadiazole skeleton, a triazole skeleton, a silole skeleton, a styrylarylene skeleton, a pyrazoloquinoline skeleton, an oligothiophene skeleton, a rylene skeleton, a perinone skeleton, a vinyl carobazole skeleton, a tetraphenylethylene skeleton, a coumarin skeleton, a rubrene skeleton, a quinacridone skeleton, a squarylium skeleton, a porphyrin skeleton, and a pyrazoline skeleton.

In particular, it may be preferable, but not limited to, that Y includes a skeleton selected from a triarylamine skeleton, a xylene skeleton, an anthracene skeleton, a styrylarylene skeleton, and a quinacridone skeleton.

The triarylamine skeleton as referred herein means a skeleton having a general structure of NArAr′Ar″, wherein Ar, Ar′ and Ar″ each represent an independently selected, optionally substituted aryl group or heteroaryl group. In an exemplary embodiment according to the present application, two of the optionally substituted aryl groups or heteroaryl groups in the triarylamine skeleton may combine to form a heterocyclic group via any desired positions. Examples of the heterocyclic group include, for example, a carbazole, a phenoxazine, a phenothiazine and a dihydrophenazine. The optionally substituted aryl group or heteroaryl group can be bonded to other aromatic groups or heterocyclic aromatic groups via any desired positions.

The rylene skeleton as referred herein means a skeleton in which naphthalene units are linked in peri-positions, including, but not limited to, a skeleton of perylene, terrylene or quaterrylene, or diimide thereof.

The styrylarylene skeleton may include a distyrylarylene skeleton and a substituted distyrylarylene skeleton in which a substituted or an unsubstituted p-phenylene group positioned in a center part of a distyrylarylene compound is substituted, for example, by a substituted or an unsubstituted 4, 4′-biphenylene group.

In an exemplary embodiment, in particular, a structural unit represented by a general formula (I): —[Y]— may be a structure represented by the following formula (I):

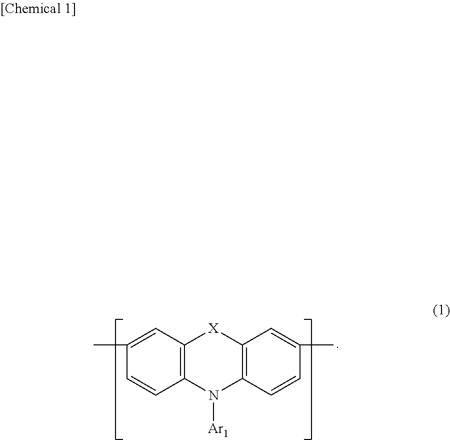

(wherein X is O or S, Ar₁ is a substituted or an unsubstituted aryl group, heteroaryl group or aralkyl group.)

A substituted or an unsubstituted aryl group may have from about 6 to about 24 carbon atoms and may include a group having a fused ring or a group in which more than one benzene rings or fused rings may each be bonded directly or via a group such as vinylene group, and examples include, for example, but not limited to, a phenyl group, a naphthyl group, an anthryl group, a phenanthryl group, a naphthacenyl group, a pyrenyl group, a chrysenyl group, a fluoranthenyl group, a biphenyl group, a tolyl group and a terphenyl group.

A substituted or an unsubstituted heteroaryl group may have from about 4 to about 24 carbon atoms and may also include a group having a fused ring or a group in which more than one fused rings may each be bonded directly or via a group such as vinylene group, and examples include, for example, but not limited to, a pyrrolyl group, a pyrazinyl group, a pyridinyl group, a quinolinyl group, an isoquinolinyl group, a quinoxalinyl group, a phenanthridinyl group, an acridinyl group, a triazinyl group, a triazolyl group and a benzotriazolyl group.

A substituted or an unsubstituted aralkyl group may have from about 7 to about 24 carbon atoms, and examples of the substituted or the unsubstituted aralkyl group may include, but not limited to, a benzyl group, a phenethyl group and a naphthylmethyl group.

Examples of a substituent on an aryl group, heteroaryl group or aralkyl group may include, for example, but not limited to, a straight or branched alkyl group such as a methyl group, an ethyl group, a propyl group, a butyl group, a pentyl group, a hexyl group; a cycloalkyl group such as a cyclopropyl group, a cyclobutyl group, a cyclopentyl group, a cyclohexyl group, a cycloheptyl group; an alkenyl group such as a vinyl group, an allyl group, a propenyl group, a cyclopropenyl group, a cyclobutenyl group, a cyclopentenyl group; an aryl group such as the groups described above; a heteroaryl group such as the groups described above; an aralkyl group such as the groups described above; an acyl group such as an acetyl group, a propionyl group, an acryloyl group, a pivaloyl group, a cyclohexylcarbonyl group, a benzoyl group, a naphtoyl group, a toluoyl group; a carboxyl group; an alkoxycarbonyl group such as a rriethoxycarbonyl group, an ethoxycarbonyl group; an aryloxycarbonyl group such as a phenoxycarbonyl group; a cyano group; a halogen group; a nitro group; an alkoxyl group such as a methoxyl group, an ethoxyl group, a propoxyl group, a butoxyl group, a pentyloxyl group, a hexyloxyl group, a heptyloxyl group, a benzyloxyl group; an aryloxyl group such as a phenoxyl group, a toluyloxyl group, a naphtyloxyl group; an amino group such as dimethylamino group, a diethylamino group, a dipropylamino group, a dibutylamino group, a methylethylamino group, a methylpropylamino group, a methylbutylamino group, a diphenylamino group; a heterocyclic amino group such as a morpholino group, a piperidino group, a piperazinyl group, a pyrazolidinyl group, a pyrrolidine group, an indolyl group; an imino group; and a carbamoyl group. Those groups may include various isomers.

A preferable example of a structural unit of a general formula (I): —[Y]— represented by the above-described formula (1) may be a structure represented by the following formula (2):

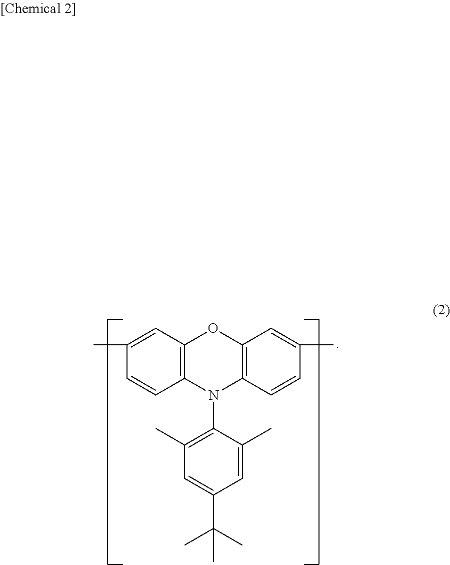

In an exemplary embodiment, Y in a structural unit represented by a general formula (I): —[Y]— may include a perylene skeleton.

In the presently illustrated embodiment, the perylene skeleton may be substituted, and examples of the perylene may include, but not limited to, a tetrasubstituted perylene which has substituents at 1, 6, 7 and 12 positions or 2, 5, 8 and 11 positions on a perylene skeleton, and a disubstituted perylene which has substituents at 1 and 6 positions or 1 and 7 positions. Further, the perylene skeleton may be a perylene to which a tetracarboxylic anhydride skeleton or a tetracarboxydiimide skeleton is introduced. In this case, an imide group on the tetracarboxydiimide skeleton may be substituted. A definition and specific examples for substituents are similar to the definition and specific examples for the substituents described for the above-described aryl group, heteroaryl group and aralkyl group when they have a substituent.

In the presently illustrated embodiment, it may be particularly preferable that a structural unit represented by a general formula (I): —[Y]— may be a structure represented by the following formula (3):

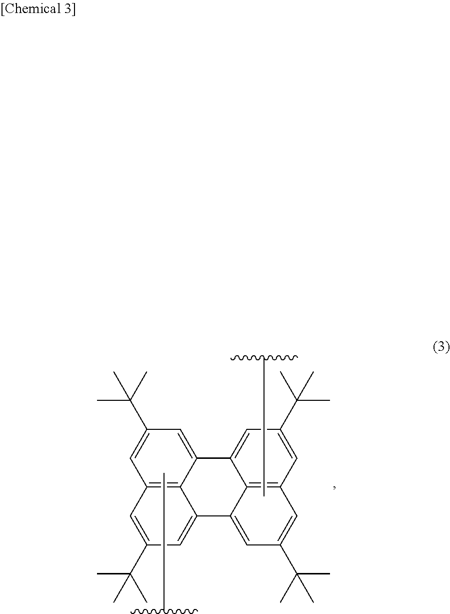

wherein an atomic bonding on an aromatic hydrocarbon ring represents that the atomic bonding can be located at any substitutable positions on the ring.

In an exemplary embodiment, in particular, a structural unit represented by a general formula (I): —[Y]— may be a structure represented by the following formula (4):

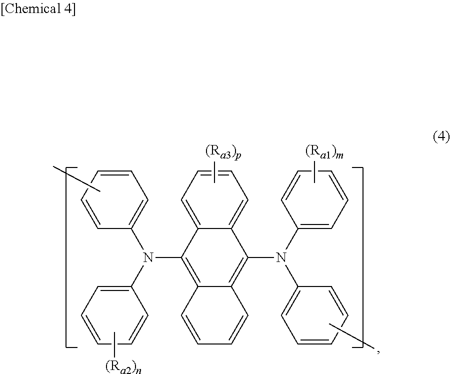

wherein an atomic bonding on an aromatic hydrocarbon ring represents that the atomic bonding can be located at any positions on the ring.

In the formula, Rₐ₁, Rₐ₂ and Rₐ₃ may independently represent an hydrogen atom, a substituted or an unsubstituted, linear, cyclic or branched alkyl group, a substituted or an unsubstituted aryl group, a substituted or an unsubstituted heteroaryl group, or a substituted or an unsubstituted aralkyl group, m and n may be independently an integer from 0 to 5 respectively, and p may be an integer from 0 to 8.

In an exemplary embodiment, in the above-described formula (4), m substituents may be selected as Rₐ₁ from the group consisting of R_{b1}, R_{b2}, R_{b3}, R_{b4} and R_{b5}, provided that in is an integer from 1 to 5, and R_{b1}, R_{b2}, R_{b3}, R_{b4} and R_{b5} may independently represent a substituted or an unsubstituted, linear, cyclic or branched alkyl group, a substituted or an unsubstituted aryl group, a substituted or an unsubstituted heteroaryl group, or a substituted or an unsubstituted aralkyl group.

In an exemplary embodiment, in the above-described formula (4), n substituents may be selected as Rₐ₂ from the group consisting of R_{c1}, R_{c2}, R_{c3}, R_{c4} and R_{c5}, provided that in is an integer from 1 to 5, and R_{c1}, R_{c2}, R_{c3}, R_{c4} and R_{c5} may independently represent a substituted or an unsubstituted, linear, cyclic or branched alkyl group, a substituted or an unsubstituted aryl group, a substituted or an unsubstituted heteroaryl group, or a substituted or an unsubstituted aralkyl group.

In an exemplary embodiment, in the above-described formula (4), p substituents may be selected as Rₐ₃ from the group consisting of R_{d1}, R_{d2}, R_{d3}, R_{d4}, R_{d5}, R_{d6}, R_{d7} and R_{d8}, provided that p is an integer from 1 to 8, and R_{d1}, R_{d2}, R_{d3}, R_{d4}, R_{d5}, R_{d6}, R_{d7} and R_{d8} may independently represent a substituted or an unsubstituted, linear, cyclic or branched alkyl group, a substituted or an unsubstituted aryl group, a substituted or an unsubstituted heteroaryl group, or a substituted or an unsubstituted aralkyl group.

Examples of a substituted or an unsubstituted alkyl group include, for example, a straight or branched alkyl group having from 1 to 12 carbon atoms and a cycloalkyl group having from 3 to 10 ring-forming carbon atoms.

Specific examples of a substituted or an unsubstituted aryl group, a substituted or an unsubstituted heteroaryl group and a substituted or an unsubstituted aralkyl group may include groups similar to the specific examples described for the aryl group, heteroaryl group and aralkyl group in a repeating unit represented by the above-described general formula (I). Further, a definition and specific examples for a substituent for each group are similar to the definition and specific examples for the substituents described for the aryl group, heteroaryl group and aralkyl group in a repeating unit represented by the above-described general formula (I) when they have a substituent.

It may be preferable that Rₐ₁ and Rₐ₂ independently represent a hydrogen atom, a substituted or an unsubstituted, linear, cyclic or branched alkyl group, and Rₐ₃ represents a hydrogen atom, in a structural unit represented by a general formula (I): —[Y]— shown by the above-described formula (4).

A further preferable example of a structural unit of a general formula (I): —[Y]— represented by the above-described formula (4) may be a structure represented by the following formula (5):

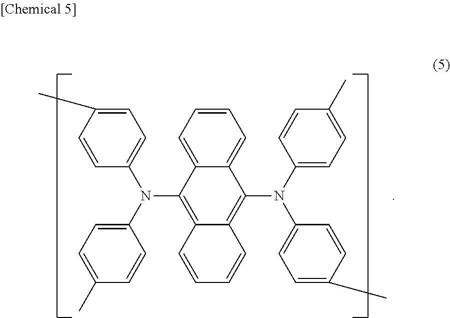

An oligomer of an organic material to be used for an organic material of the organic EL light-emitting element of the presently illustrated embodiment may be preferably an oligomer having a polymerization degree of from 2 to 10, i.e. an oligomer of from a dimer to an icosamer. In other words, it may be preferable that an oligomer according to the presently illustrated embodiment is a compound formed by a polymerization of 2 or more and 10 or less of the monomers containing the structural unit described above. It may be particularly preferable that an oligomer according to the presently illustrated embodiment is a compound formed by a polymerization of 2 or more and 5 or less of monomers containing the structural unit described above.

When an oligomer has a polymerization degree of this range, it can be highly purified by using a purification method such as column chromatography and gel permeation chromatography. It is considered that an occurrence of a luminance unevenness, which has been considered as a problem caused due to a molecular weight distribution of the polymer compounds in a conventional coating method using a polymer compound as an organic material, can be reduced.

An oligomer of the organic material of the exemplary embodiment may be prepared by a polymerization of the above-described, structural unit-containing monomers, which are the polymerizable monomers that have more than one polymerizable groups. Examples of the polymerizable group include, for example, a halogen atom, a sulfonate group, an alkyl sulfonate group, an arylsulfonate group, an arylalkylsulfonate group, a boronic acid group (—B(OH₂), a borate ester residue, a methylsulfonium group, a methylphosphonium group, a methylphosphonate group, a monohalogenated methyl group, a formyl group, a cyano group and a vinyl group. Exemplary examples of a particularly preferable substituent as a polymerizable substituent, which may vary depending on the types of polymerization reaction and the catalyst used for polymerization reaction, may include a halogen atom, selected from a chlorine atom, a bromine atom and iodine atom, an alkyl sulfonate group, a boronic acid group and a borate ester residue. A bromine atom may be particularly preferable as a halogen atom. A polymerizable monomer containing a bromine atom can be prepared by a well-known method, for example, by using N-bromosuccinimide. Examples of the borate ester residue may include, for example, a group represented by the following formulae.

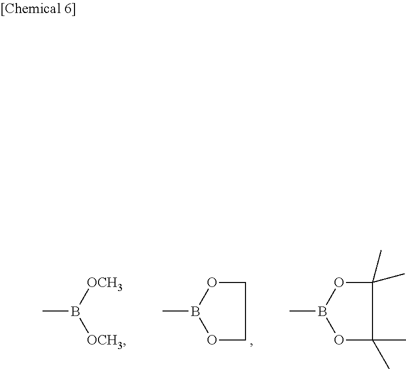

A polymerizable monomer containing a boronic acid group or a borate ester residue can be prepared by a well-known method, for example, a transmetallation with, for example, trimethyl borate or triisopropyl borate of the corresponding organometallic reagent prepared from the monomer containing the above-described structural unit using a Grignard reagent or lithium and the like; a Br (or I)—B exchange reaction using a bis(pinacolato)diboron of polymerizable monomer containing a bromine atom or iodine atom and a palladium catalyst; or a direct borylation via C—H bond activation using an iridium catalyst or a ruthenium catalyst.

A polymerization method to be used is not particularly limited and a general coupling reaction can be used. Examples of the preferable coupling reaction include coupling reactions such as Suzuki coupling, Stille coupling, Yamamoto coupling, Heck coupling, Hartwig-Buchwald coupling, Sonogashira coupling, Negishi coupling, Hiyama coupling and Gilch coupling. Among them, Suzuki coupling in which a dihalide derivative of the polymerizable monomer and a diboronic or boronic ester derivative are cross-coupled using a proper catalyst may be preferable in terms of a structure controlling. Examples of the proper catalyst may include a Pd or Ni complex with a ligand of phosphine compound or N-heterocyclic carbene, and alumina-supported ruthenium catalyst. A base may be used in the coupling reaction as needed. Examples of a proper base may include an inorganic base, such as potassium carbonate, sodium carbonate and tripotassium phosphate, and an organic base, such as triethylamine and tetrabutylammonium bromide. Preferably, a cupping reaction is conducted in a solvent, such as N, N-dimethyl formamide, toluene and tetrahydrofuran, under an inert atmosphere, such as argon atmosphere and nitrogen atmosphere. A reaction time and/or a reaction temperature for the coupling reaction is not particularly limited and may be set such that a desired polymerization degree can be obtained. The reaction may be conducted under reflux, alternatively, the reaction temperature may be increased or decreased in the middle of the reaction so as to obtain a desired polymerization degree. To obtain an oligomer with a desired polymerization degree, a polymerization reaction may be terminated by, for example, removing a catalyst from the reaction system during the reaction. However, even when the yield of the oligomer having an aimed polymerization degree is low, the aimed oligomer can be fractionated and purified using a method such as column chromatography.

The prepared oligomer of an organic material can be highly purified by, for example, a separation using the above-described chromatography, a reprecipitation or a recrystallization. By using a purified oligomer with a high purity as an organic material, an organic EL light-emitting element having a superior optical property, including a superior light emission lifetime, can be realized.

An oligomer of an organic material to be used for an organic material of the organic EL light-emitting element of the presently illustrated embodiment may be an oligomer obtained by polymerizing more than one structural units selected from the above-described structural units. In this case, a molar ratio of each structural unit in the oligomer of the organic material to be prepared may be adjusted such that a desired property including a desired light-emission property, which is required as a material for the organic layer 26 of an organic EL light-emitting element, can be obtained. The oligomer of this kind of copolymer can be synthesized by a well-known method, for example, by a coupling reaction such as the above-described Suzuki coupling. For example, the above-described polymerizable monomer containing a bromine atom is coupled with the above-described polymerizable monomer having a borate ester residue. The same catalyst, solvent and reaction conditions and the like as those described above can be adopted. By adjusting a ratio of the starting materials (for example, a polymerizable monomer containing a bromine atom and a polymerizable monomer having a borate ester residue) to be used for the polymerization, an oligomer having a desired polymerization degree and a desired molar ratio of the structural units can be synthesized.

Further, an oligomer of an organic material to be used for an organic material of the organic EL light-emitting element of the presently illustrated embodiment may be not only an oligomer formed by a polymerization of the structural unit represented by —[Y]— but also an oligomer in which a structural unit represented by —[Y] is incorporated in a main chain of the oligomer by other polymerizable linking groups. Examples of such an oligomer may include an oligomer formed by a polymerization of a structural unit represented by the following general formula (II):

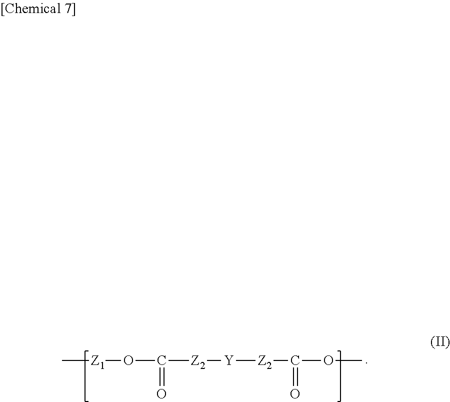

In the general formula (II), Y may be same as Y defined in the general formula (I), and Z₁ and Z₂ may each represent a saturated or an unsaturated alkyl group. Thus, in this example, the oligomer is an oligomer of a polyester condensation polymer having a structural unit represented by —[Y]—. By introducing a structural unit represented by —[Y]— into an oligomer in this way, the synthesis of an oligomer and/or the polymerization may be conducted easily. From the viewpoint of the ease of condensation polymerization, a dimethylene group may be particularly preferable as Z₁.

Further, an oligomer of an organic material to be used for an organic material of the organic EL light-emitting element of the presently illustrated embodiment may include not only a main chain type oligomer in which the main chain structure is constituted by a structural unit represented by a general formula (I): —[Y]—, but also a conjugated oligomer having a unit constituted by such a structural unit on a side chain. Such an oligomer may be prepared by introducing a unit constituted by the above-described structural unit into a desired monomer having a polymerizable group and by conducting a polymerization reaction of monomers.

In one embodiment of the present application, an organic layer 26 of the organic EL light-emitting element may include one or more organic materials which have a superior property such as a hole transport property or an electron transport property, in addition to the light-emitting organic material, as described above. For example, a coating solution 25a containing a composition formed by mixing an oligomer of an organic material which is a light-emitting material and a compound having a hole transport property or an electron transport property may be used for a formation of the organic layer 2E. An oligomer of different kinds of organic materials, for example, an oligomer as a light-emitting material and an oligomer having a hole transport property, may be mixed and used to form an organic layer 26 through a coating process. It should be noted that a combination of the materials is not limited to those described above. This may enable to reduce a number of layers in the organic layer 26 of the organic EL light-emitting element. This may improve a flatness of the organic layer 26 and prevent an occurrence of a display unevenness such as a luminance unevenness or a light emission color unevenness when the organic layer 26 emits light.

Referring to a flowchart in FIG. 4, an method of manufacturing an organic EL light-emitting element according to the second embodiment of the present application include forming a first electrode 22 on a surface of a substrate 21 (S1), forming an insulation bank 23 to surround at least part of the first electrode 22 (S2), forming a coated-type organic layer 26 on an area of the first electrode 22 surrounded by the insulation bank 23 (S3), and forming a second electrode 27 on the organic layer 26 (S4). This organic layer 26 is formed by dropping a droplet of a liquid composition comprising the above-described oligomer of an organic material using an ink-jet process. More detailed description will be followed.

When applying the light-emitting element to an organic EL display apparatus, as described above, a driving TFT, for example, which forms a driving circuit on the substrate 21, is formed with an amorphous semiconductor, for example, by a usual method using a lithography process, for example. It is planarized by, for example, using a polyimide resin to planarize irregularities of the surface. The first electrode 22 is formed in matrix form according to an arrangement of each pixels on its surface. This first electrode 22 is also formed by forming the above-described material for electrode on the entire surface and being subjected to a patterning process (S1).

Subsequently, the insulation bank 23 is formed (S2). This insulation bank 23 may be formed by an inorganic material such as a silicon oxide, a silicon nitride, a silicon oxynitride, or, if a thicker layer is required, the insulation bank 23 may be formed in a short time by forming it with a material such as an acrylic resin, a polyimide resin or a novolak-type phenol resin. For example, an insulation bank 23, which includes an opening 23a that exposes at least part of the first electrode inside thereof as illustrated in FIG. 1A, is formed by forming an insulation layer on the entire surface with a thickness of, for example, about 1 μm, which should provide a sufficient height for an insulation bank 23, and (ii) being subjected to a pattering process using a photolithography technique. In this case, an insulation bank 23 may be formed in a forward tapered shape.

Then, a coating solution 25a of the above mentioned organic material is ejected from a nozzle 31 by an ink-jet process, as illustrated in FIG. 1A. The ejection of the coating solution 25a is conducted by aligning the nozzle 31 to the first electrode 22 exposed in the opening 23a surrounded by the insulation bank 23. As illustrated in FIG. 1B, an ejected coating solution 25a forms a coated layer 25 in the opening 23a surrounded by the insulation bank 23 (S3).

In particular, as illustrated in FIG. 1A, a coating solution 25a of an organic material containing the oligomer according to the embodiment of the present application is ejected from a nozzle 31 of the ink-jet apparatus and drips on an area of the first electrode 22 surrounded by the insulation bank 23. A coating solution 25a may be a liquid composition containing at least an oligomer according to the embodiment of the present application and a solvent. Any solvents capable of dissolving an organic material containing an oligomer according to the embodiment of the present application may be used, and preferably an organic solvent may be used. Examples of the organic solvent is not particularly limited, however, when a low-boiling point solvent is used as a solvent, this would cause a clogging in the nozzle of ink-jet apparatus, or, a thickness unevenness would be occurred since drying of a coating solution 25a may begin right after being ejected from a nozzle 31 and a solute may be precipitated. Therefore, a low-boiling point solvent may be preferably used in combination with a solvent having a higher boiling point. For example, as the solvent, a chlorine based solvent, ether based solvent, aromatic hydrocarbon based solvent, aliphatic hydrocarbon based solvent, ketone based solvent, ester based solvent, alcohol based solvent, amide based solvent, and a mixed solvent thereof are exemplified. Among them, a mixed solvent containing cyclohexylbenzene, xylene or anisole, or one or more of those may be preferable in terms of, for example, an evenness of a formed layer and viscosity property of a coating solution 25a, but a solvent is not limited to those. A coating solution 25a may be prepared to have a viscosity at 25° C. of about 0.6×10⁻³ Pa·s or more and about 3×10⁻³ Pa·s or less, preferably about 1×10⁻³ Pa·s or less. With a viscosity of this range, a coating solution 25a can be ejected from an ink-jet head as a droplet having a substantially constant particle diameter, and a steady ejection from the ink-jet apparatus can be realized even when using an apparatus provided with multiple nozzles.

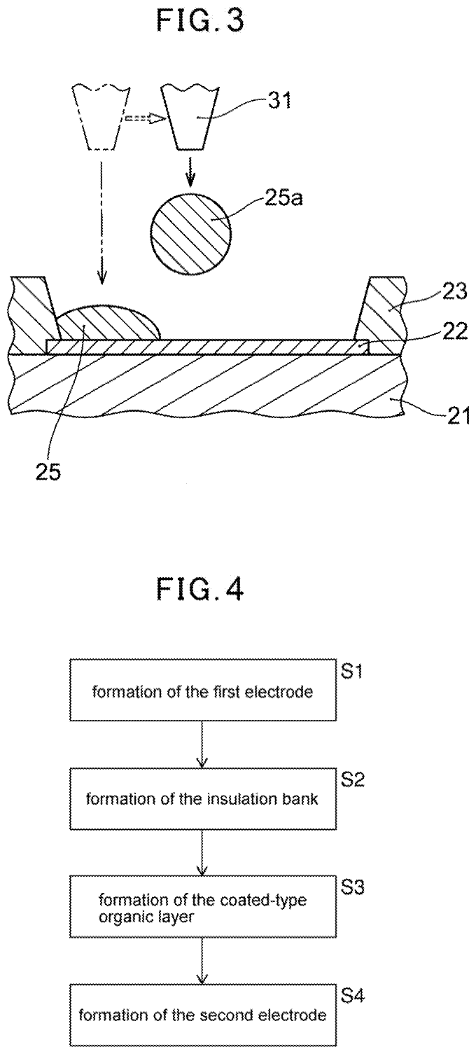

In this case, when an area surrounded by the insulation bank 23 has a long narrow rectangular shape, a coated layer 25 may be formed on an entire surface of the first electrode 22 surrounded by the insulation bank 23 by ejecting a coating solution two or more times while relatively shifting the positions of the nozzle 31 and the substrate 21, as illustrated in FIG. 3. By drying and baking this coated layer 25, a coated-type organic layer 26 formed with an organic material containing an oligomer according to the embodiment of the present application can be formed on the first electrode 22.

Subsequently, a eutectic layer composed of magnesium and silver, for example, is formed by, for example, a vapor-deposition on the entire surface to form a second electrode 27 on the organic layer 26 (S4). In the organic EL light-emitting element according to the presently illustrated embodiment, the second electrode 27 serves as a cathode. An example of the material which constitutes a second electrode 27 is as described above, and the second electrode 27 is formed to have a thickness of about 5 nm or more and about 30 nm or less. The second electrode 27 is formed on the entire surface including the top surface of the insulation bank 23, since it is formed as a common electrode for each pixel.

Next, a barrier layer 28 which serves as a seal layer to prevent a penetration of water and/or oxygen from the outside is formed on the second electrode 27. This barrier layer 28 may be an inorganic layer formed of, for example, Si₃N₄ or SiO₂, which has no hygroscopic property and may be formed by bonding to a substrate 21 (not indicated) in such a way to entirely cover the second electrode 27 and organic layer 26 and so on. Consequently, the organic EL light-emitting element of the embodiment of the present application is completed (see FIG. 1C). This method is described herein as merely an exemplary example, and a method of manufacturing an organic EL light-emitting element of the embodiment of this application may further include optional steps between each step. For example, when a coating solution 25a is dropped multiple times on different positions in an area surrounded by the insulation bank 23 as described above, a planarization process may be conducted to planarize a coating solution 25a dripped in the area before the drying process of the coated layer 25.

As described above, by using an organic material containing an oligomer according to the presently illustrated embodiment as an organic material for the organic layer 26 of the organic EL light-emitting element, a coated-type organic layer 26 can be provided on a small-sized area on the electrode. Further, a display unevenness such as a thickness unevenness can be reduced, and an organic EL light-emitting element with a high definition pattern having a superior light-emission property can be obtained at a low cost.

Summary

(1) An organic electroluminescent light-emitting element according to the first embodiment of the present application includes a substrate, a first electrode provided on a surface of the substrate, an insulation bank formed to surround at least part of the first electrode, an organic layer formed on the first electrode surrounded by the insulation bank, and a second electrode formed on the organic layer, wherein the organic layer is a coated-type organic layer comprising an oligomer of an organic material, and the oligomer has a molecular weight of 300 or more and 5000 or less.

According to the organic EL light-emitting element of the exemplary embodiment of the present application, a volume per one drop of a liquid drop of a liquid composition to be ejected from a nozzle of the ink-jet apparatus to form a coated layer can be small since the organic material to form a coated-type organic layer contains an oligomer having a molecular weight of 300 or more and 5000 or less, preferably 1000 or less, and thus, there is no possibility that a liquid composition overflows the insulation bank and spreads to the electrodes of neighboring pixels. A high definition pattern formation of pixels can be realized by coating process. A coated-type organic layer with a good quality is precisely formed even on a small-sized pixel electrode of an organic EL light-emitting element.

(2) It may be preferable that the oligomer is a polymer of monomers each comprising a structural unit represented by a general formula (I): —[Y]—, wherein Y comprises a skeleton selected from a group consisting of a triarylamine skeleton, a rylene skeleton, an anthracene skeleton, a distyrylarylene skeleton and a quinacridone skeleton. With an organic layer of an organic EL light-emitting element containing such an oligomer, a superior optical property can be obtained.

(3) It may be preferable that the oligomer is a polymer formed by a polymerization of 2 or more and 10 or less of the monomers. With an organic layer of an organic EL light-emitting element containing such an oligomer, a coated-type organic layer with a small size and a high definition pattern is formed.

(4) It may be preferable that the structural unit has a structure represented by the following formula (1):

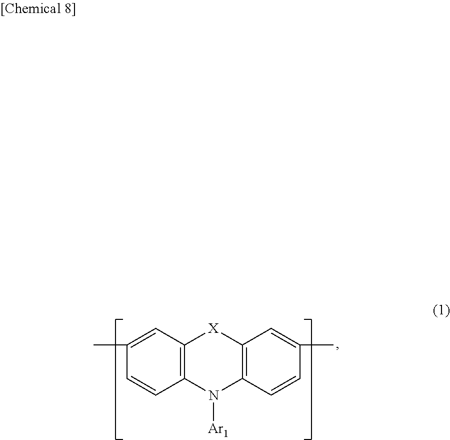

wherein X is O or S, and Ar₁ is a substituted or an unsubstituted aryl group, heteroaryl group or aralkyl group. With an organic layer of an organic EL light-emitting element containing such an oligomer, a superior optical property can be obtained.

(5) It may be preferable that the structural unit has a structure represented by the following formula (2):

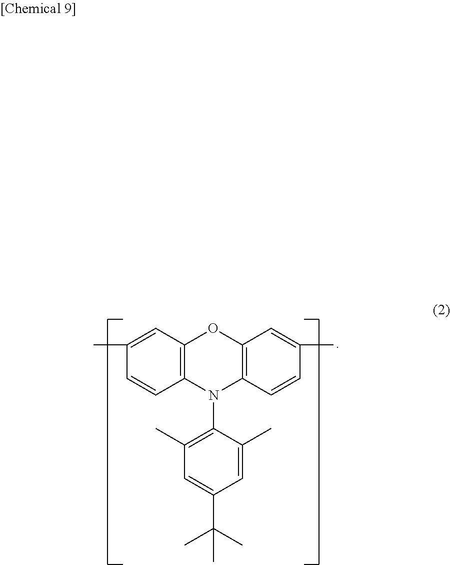

With an organic layer of an organic EL light-emitting element containing such an oligomer, a superior optical property can be obtained.

(6) It may be preferable that Y in the structural unit comprises a perylene skeleton. With an organic layer of an organic EL light-emitting element containing such an oligomer, a superior optical property can be obtained.

(7) It may be preferable that the structural unit has a structure represented by the following formula (3):

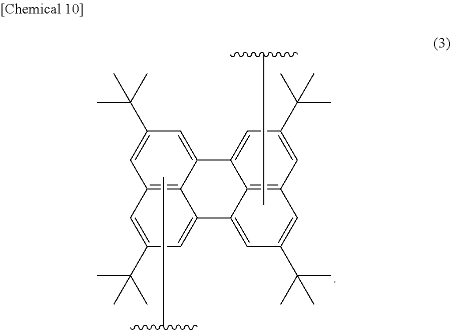

With an organic layer of an organic EL light-emitting element containing such an oligomer, a superior optical property can be obtained.

(8) It may be preferable that the structural unit has a structure represented by the following formula (4):

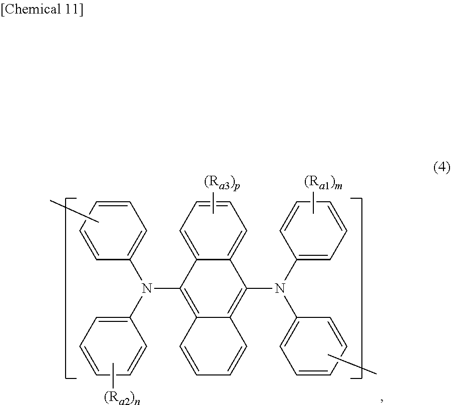

wherein Rₐ₁, Rₐ₂ and Rₐ₃ may independently represent an hydrogen atom, a substituted or an unsubstituted, linear, cyclic or branched alkyl group, a substituted or an unsubstituted aryl group, a substituted or an unsubstituted heteroaryl group, or a substituted or an unsubstituted aralkyl group, m and n may be independently an integer from 0 to 5 respectively, and p may be an integer from 0 to 8. With an organic layer of an organic EL light-emitting element containing such an oligomer, a superior optical property can be obtained.

(9) It may be preferable that the Rₐ₁ and the Rₐ₂ independently represent a hydrogen atom, a substituted or an unsubstituted, linear, cyclic or branched alkyl group, and the Rₐ₃ represents a hydrogen atom. With an organic layer of an organic EL light-emitting element containing such an oligomer, a superior optical property can be obtained.

(10) It may be preferable that the structural unit has a structure represented by the following formula (5):

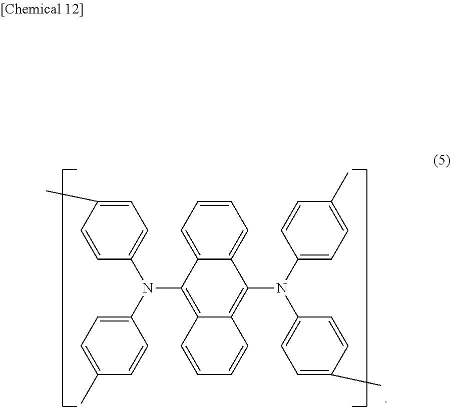

With an organic layer of an organic EL light-emitting element containing such an oligomer, a superior optical property can be obtained.

(11) Further, a method of manufacturing an organic electroluminescent light-emitting element of the second embodiment of the present application includes forming a first electrode on a surface of a substrate, forming an insulation bank to surround at least part of the first electrode, forming a coated-type organic layer on an area of the first electrode surrounded by the insulation bank, and forming a second electrode on the organic layer, wherein a step for forming the organic layer is conducted by applying a droplet with a volume of 0.05 pL or more and 1 pL or less of a liquid composition comprising an oligomer of an organic material using an ink-jet process.

According to the method of manufacturing an organic EL light-emitting element of the second embodiment of the present application, an organic EL light-emitting element, in which an organic layer is formed with a high definition pattern on a pixel electrode by a coating process, can be obtained even when it has a small-sized pixel. Therefore, a small-sized, high definition organic EL light-emitting element can be manufactured easily and inexpensively.

(12) It may be preferable that a concentration of the oligomer in the liquid composition is 10 mass % or more to 30 mass % or less, since this enables an effective formation of the organic layer even on a small-sized light-emitting area.

(13) It may be preferable that the liquid composition has a viscosity of 0.6×10⁻³ Pa·s or more and 3×10⁻³ Pa·s or less, since this enables a steady ejection of the liquid composition from an ink-jet nozzle as a small droplet.

(14) When an ejection during the ink-jet process is conducted by moving a nozzle for ejecting the liquid composition within a range of an area surrounded by the insulation bank, an occurrence of a thickness unevenness can be prevented in the coated-type organic layer to be formed.

### DESCRIPTION OF REFERENCE NUMERALS

21 substrate
22 first electrode
23 insulation bank
23a opening
25 coated layer
25a coating solution
26 organic layer
27 second electrode
28 barrier layer
31 nozzle

1. An organic electroluminescent light-emitting etc comprising:
a substrate,
a first electrode provided on a surface of the substrate,
an insulation bank formed to surround at least part of the first electrode,
one or more organic layers formed on the first electrode surrounded by the insulation bank, and
a second electrode formed on the organic layer,
wherein each of the one or more organic layers is a coated-type organic layer formed of an oligomer having a molecular weight of 300 or more and 5000 or less of an organic material, and the one or more organic layers comprise a light-emitting layer,
the oligomer of the organic material for the light-emitting layer is a polymer of monomers each comprising a structural unit represented by a general formula (I): —[Y]—, wherein Y comprises a skeleton selected from a group consisting of a triarylamine skeleton, a rylene skeleton, an anthracene skeleton, a distyrylarylene skeleton and a quinacridone skeleton, and
an area of the first electrode surrounded by the insulation bank is 100 μm² or more and 2500 μm² or less.

2. (canceled)

3. The organic electroluminescent light-emitting element of claim 1, wherein the oligomer of the organic material for the light-emitting layer is a polymer formed by a polymerization of 2 or more and 10 or less of the monomers.

4. The organic electroluminescent light-emitting element of claim 1, wherein the structural unit has a structure represented by a following formula (1): 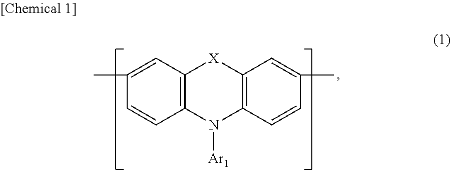
wherein X is O or S, and Ar₁ is a substituted or an unsubstituted aryl group, heteroaryl group or aralkyl group.

5. The organic electroluminescent light-emitting element of claim 4, wherein the structural unit has a structure represented by a following formula (2):

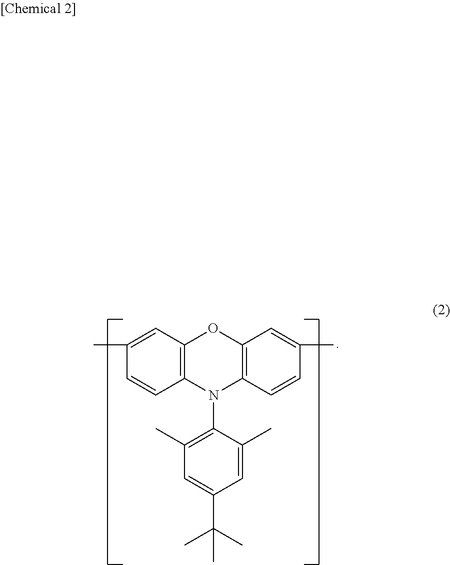

6. The organic electroluminescent light-emitting element of claim 1, wherein the Y in the structural unit comprises a perylene skeleton.

7. The organic electroluminescent light-emitting element of claim 6, wherein the structural unit has a structure represented by a following formula (3):

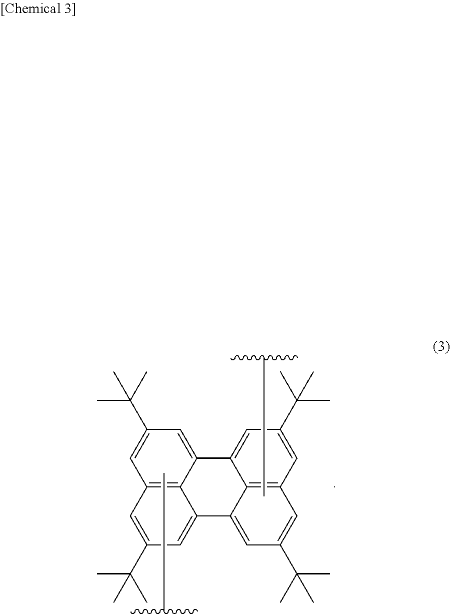

8. The organic electroluminescent light-emitting element of claim 1, wherein the structural unit has a structure represented by a following formula (4): 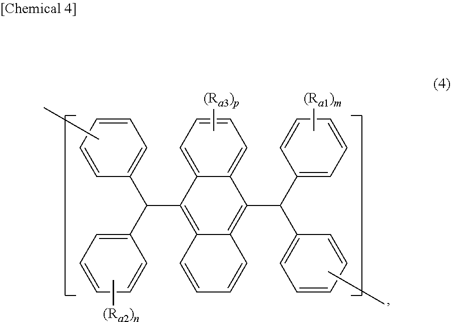
wherein Rₐ₁, Rₐ₂ and Rₐ₃ may independently represent a group selected from the group consisting of an hydrogen atom, a substituted or an unsubstituted, linear, cyclic or branched alkyl group, a substituted or an unsubstituted aryl group, a substituted or an unsubstituted heteroaryl group and a substituted or an unsubstituted aralkyl group, m and n may be independently an integer from 0 to 5 respectively, and p may be an integer from 0 to 8.

9. The organic electroluminescent light-emitting element of claim 8, wherein the Rₐ₁ and the Rₐ₂ independently represent a hydrogen atom, a substituted or an unsubstituted, linear, cyclic or branched alkyl group, and the Rₐ₃ represents a hydrogen atom.

10. The organic electroluminescent light-emitting element of claim 9, wherein the structural unit has a structure represented by a following formula (5):

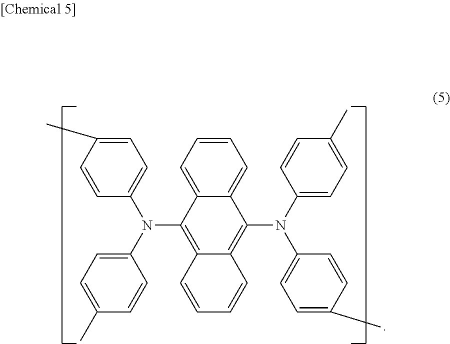

11. A method of manufacturing an organic electroluminescent light-emitting element comprising:
forming a first electrode on a surface of a substrate,
forming an insulation bank to surround at least part of the first electrode,
forming one or more organic layers comprising a light-emitting layer on an area of the first electrode surrounded by the insulation bank, each of the one or more organic layers being formed of an oligomer having a molecular weight of 300 or more and 5000 or less of an organic material as a coated-type organic layer, and
forming a second electrode on the organic layer,
wherein the oligomer of the organic material for the light-emitting layer is a polymer of monomers each comprising a structural unit represented by a general formula (I): —[Y]—, wherein Y comprises a skeleton selected from a group consisting of a triarylamine skeleton, a rylene skeleton, an anthracene skeleton, a distyrylarylene skeleton and a quinacridone skeleton,
a step for forming the light-emitting layer is conducted by applying a droplet with a volume of 0.05 pL or more and 1 pL or less of a liquid composition comprising the oligomer of the organic material using an ink-jet process.

12. The method of manufacturing an organic electroluminescent light-emitting element of claim 11, wherein a concentration of the oligomer in the liquid composition is 10 mass % or more to 30 mass % or less.

13. The method of manufacturing an organic electroluminescent light-emitting element of claim 11, wherein the liquid composition has a viscosity of 0.6×10⁻³ Pa·s or more and 3×10⁻³ Pas or less.

14. The method of manufacturing an organic electroluminescent light-emitting element of claim 11, wherein an ejection during the ink-jet process is conducted by moving a nozzle for ejecting the liquid composition within a range of an area surrounded by the insulation bank.
